(19) United States
(12) Patent Application Publication
(10) Pub. No.: US 2025/0070742 A1
(43) Pub. Date: Feb. 27, 2025

(54) Hybrid Sectional-Bifilar Wound Filters

(71) Applicant: WiTricity Corporation, Watertown, MA (US)

(72) Inventor: Nam Hoai Lee, Birr (CH)

(73) Assignee: WiTricity Corporation, Watertown, MA (US)

(21) Appl. No.: 18/794,845

(22) Filed: Aug. 5, 2024

Related U.S. Application Data
(60) Provisional application No. 63/578,507, filed on Aug. 24, 2023.

(51) Int. Cl. H03H 7/42; H01F 1/153; H01F 27/28; H01F 38/14; H02J 50/12

(52) U.S. Cl. CPC H03H 7/427; H01F 1/15333; H01F 27/2823; H01F 38/14; H02J 50/12; H02J 2310/48

(57) ABSTRACT

A signal filter includes a plurality of laminations forming an annular core, a first bifilar winding wrapped around a first portion of the core, and a second bifilar winding wrapped around a second portion of the core. A wireless power transmitter includes a power input, a power converter coupled to the input and configured to provide high-frequency (HF) current, an output coil, and an output filter between the power converter and the output coil. A wireless power receiver includes an input coil, a power converter coupled to an output and configured to provide current suitable for a load, and an input filter between the input coil and the power converter.

### CROSS-REFERENCE TO RELATED APPLICATION(S)

This application claims the benefit of U.S. Provisional Patent Application Ser. No. 63/578,507 filed on Aug. 24, 2023, the disclosure of which is incorporated by reference herein in its entirety.

### FIELD

The present disclosure relates generally to wireless power transfer, and more specifically to filters within the power electronics of wireless power transfer systems. One use for such systems is wireless electric vehicle charging.

### BACKGROUND

Conventional Electric Vehicle (EV) charging systems, which convert Alternating Current (AC) power from the Grid to Direct Current (DC) power for charging the EV battery, generally include an isolation transformer, which can be shielded to suppress electromagnetic emissions. Wireless EV charging systems, in contrast, do not require an isolation transformer, as the Wireless Power Transmission (WPT) system is inherently isolated. Emissions suppression is provided by components within the charging system.

### SUMMARY

In general, in some aspects, a signal filter includes a plurality of laminations forming an annular core, a first bifilar winding wrapped around a first portion of the core, and a second bifilar winding wrapped around a second portion of the core. A wireless power transmitter includes a power input, a power converter coupled to the input and configured to provide high-frequency (HF) current, an output coil, and an output filter between the power converter and the output coil. A wireless power receiver includes an input coil, a power converter coupled to an output and configured to provide current suitable for a load, and an input filter between the input coil and the power converter.

Implementations may include one or more of the following, in any combination. The first and second portions of the core may not overlap. Each of the first and second portions of the core comprises an arc that may span less than 180 degrees of the annular core. The laminations may include nanocrystalline (NC) material. The laminations may include iron alloy material other than nanocrystalline (NC) material. Each of the first and second bifilar windings may include a respective first and second wire, with the respective first and second wires maintaining a parallel arrangement, relative to each other, when wrapped around the corresponding section of the core. Each of the first and second wires may be Litz wire. Each of the first and second wires may be solid wire.

### BRIEF DESCRIPTION OF THE DRAWINGS

FIG. 1 is a schematic diagram of a wireless power transfer system for charging one or more electric vehicles.

FIGS. 2 and 3 are a schematic diagrams of electrical elements of the wireless power transfer system of FIG. 1.

FIGS. 4A and 4B shows a filter having sectional windings.

FIGS. 5A and 5B shows a filter having bifilar windings.

FIGS. 6A and 6B shows a filter having hybrid sectional-bifilar windings.

FIG. 7 shows experimental results including thermal testing.

FIG. 8 shows a graph of impedance vs frequency.

### DETAILED DESCRIPTION

Wireless electric vehicle charging (WEVC) systems generally use switched-mode power conversion to efficiently generate a Low Frequency (LF) alternating magnetic field to wirelessly transfer power to an electric vehicle. As a result, an electrical current of base-side equipment includes harmonics of the switching frequency, which may be high frequency (HF). Harmonics are also generated at vehicle-side equipment due to nonlinear effects in power conversion from the LF current received wirelessly to DC power for battery charging. These harmonics currents may generate harmonics levels exceeding emission limits as presently specified in standards (e.g., Comité International Spécial des Perturbations Radioélectriques (CISPR), European Telecommunications Standards Institute (ETSI)). Therefore, implementation of additional harmonics mitigation techniques can help to achieve regulatory compliance of WEVC systems. “Low Frequency” should be understood in the context of radio communication frequencies (e.g., 30-300 kHz) a much higher frequency than the 50 Hz or 60 Hz frequency used for Alternating Current (AC) wired power transmission. “High Frequency” refers to frequencies between 3 and 30 Megahertz (MHz). Wireless Power Transmission (WPT) for EV charging generally operates in the LF range, while WPT for other applications may operate in the HF range.

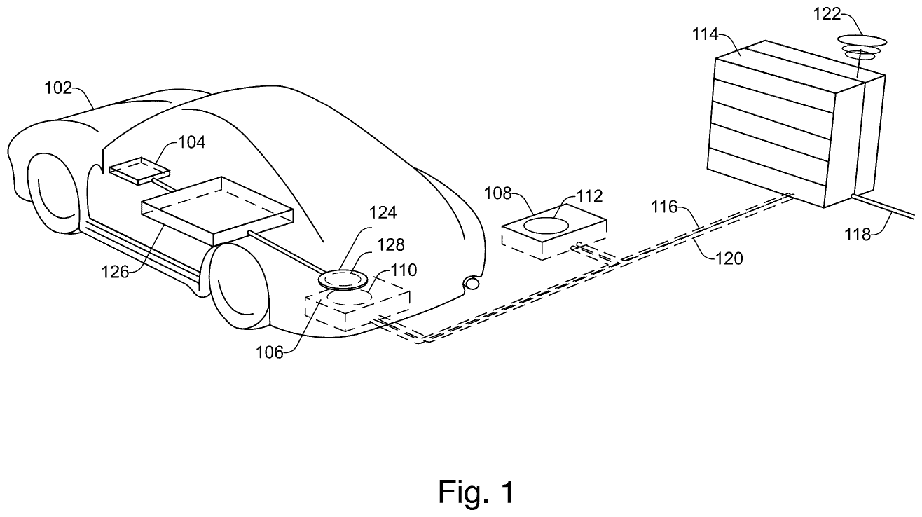

FIG. 1 is a schematic diagram of a wireless power transfer system 100 for charging one or more electric vehicles. The wireless power transfer system 100 enables the delivery of power to an electric vehicle 102. Such a system is also known as a wireless electric vehicle charging (WEVC) system because such systems are typically used to deliver power to charge a battery 104 in the electric vehicle 102. The power need not be delivered to the battery 104. Rather, it could be delivered to another load, such as an electric motor or other ancillary in the electric vehicle 102 while it is parked, including a heating system for cold mornings or an air conditioning system for hot days.

As shown, the system 100 allows charging while the electric vehicle 102 is parked in one of two parking spaces which each have an associated base power transfer apparatus 106, 108. Each base power transfer apparatus 106, 108 includes a wireless power transfer coil 110, 112 which is driven by associated control circuitry (not shown in FIG. 1) to generate a magnetic field above the base power transfer apparatus 106, 108.

Depending on specific requirements of a given implementation, the control circuitry may be supplied within the base power transfer apparatus. Alternatively, the control circuitry may be supplied partly or wholly in a unit separate from the base power transfer apparatus 106, 108, with the base power transfer apparatus 106, 108 including the wireless power transfer coil and minimal base-side control circuitry, if any, that is deemed necessary for efficient driving of the wireless power transfer coils 110, 112. The base power transfer apparatuses 106, 108 are typically installed on the ground surface or buried in the ground, although they may also be supplied as removable units that may simply be placed on the ground where required and moved to another location after use.

A power supply 114 coupled to the base power transfer apparatuses 106, 108 delivers electrical power via a power link 116. As shown, the power supply 114 is connected to a power network 118. In a domestic installation, the power supply 114 may be connected to a domestic power supply in place of the power network 118, or directly to the Grid.

In use, the power supply 114 and the base power transfer apparatus 106, 108 communicate via a communications link 120 which may be a wired or wireless connection. Alternatively, or additionally depending on the specifics of the installation, communication within the system 100 may be via a wireless link 122. The wireless link 122 may optionally also communicate with, for example, a power grid management system or other external entity via a communication backhaul to manage and control power transfer from the power grid to the system or vice versa. In the illustrated example, the power link 116 and the communications link 120 may be buried. Alternatively (e.g., in a domestic setting), they may be supplied in the form of a cable or umbilicus of connections that can be plugged into the base power transfer apparatus 106, 108 and the power supply 114.

The electric vehicle 102 includes a vehicle power transfer apparatus 124 and associated vehicle-side control circuitry 126, which controls the transfer of energy from a wireless power transfer coil 128 in the vehicle power transfer apparatus 124 to the battery 104. The vehicle-side control circuitry 126 and the base-side control circuitry communicate with each other during the transfer of power between the base power transfer apparatus 106, 108 and the vehicle power transfer apparatus 124, as will be described in greater detail herein below.

As shown, the vehicle power transfer apparatus 124 includes a wireless power transfer coil 128, and the vehicle-side control circuitry 126 is located in a different location on the vehicle 102 than the wireless power transfer coil 128. As with the base power transfer apparatus 106, 108, this separation of the wireless power transfer coil 128 and the control circuitry 126 is a matter of engineering design or selection depending on the specifics of the installation. The control circuitry 126 may be supplied partly or wholly in the vehicle power transfer apparatus 124 together with the wireless power transfer coil 128. In some vehicles it may be more convenient in terms of manufacture or servicing to combine the equipment and the wireless power transfer coil 128 in the power transfer apparatus 124 whereas, in other vehicles, separate units may be more suitable. Similar considerations apply to the separation or co-location of the control circuitry and the wireless power transfer coils 110, 112 in the base power transfer apparatus 106, 108.

In use, the vehicle 102 is so positioned in a parking space that the vehicle power transfer apparatus 124 is located over the base power transfer apparatus 106, 108 in the parking space. When the vehicle 102 is parked as shown, with the vehicle power transfer apparatus 124 placed over the base power transfer apparatus 106, 108, wireless power transfer can be employed. Electrical energy in the form of an LF current is delivered from the power supply 114 via the power link 116 to the base power transfer apparatus 106 where it drives the wireless power transfer coil 110. In other examples, the power link 116 provides AC or DC power, which is converted to LF current by power conversion circuitry in the power transfer apparatus 106, 108. This LF current causes the wireless power transfer coil 110 to create a magnetic field (Ampere's law). That field induces a voltage (Faraday's law) and an electric current in the wireless power transfer coil 128 in the vehicle power transfer apparatus 124, which current is used to drive a load. The current is converted from LF to DC or another suitable form by the control circuitry 126 and used to charge the battery 104.

It should be appreciated that the system 100 shown in FIG. 1 is a static WEVC system in that the vehicle 102, once parked, remains in place over the base power transfer apparatus 106, 108 during charging of the battery 104. Other wireless power transfer systems for electric vehicles allow power transfer to occur while the vehicle is being driven along a road, picking up energy from a charging track that serves a similar function to the base power transfer apparatus 106, 108. Such dynamic wireless electric vehicle power transfer systems are well documented and, in the interest of brevity, are not described in any further detail herein.

Usually the wireless power transfer system 100 is designed to transfer power from the power supply 114 via the power network 118 to the base power transfer apparatus 106 or 108, and on to the vehicle power transfer apparatus 124. However, because of the inherent way in which magnetic wireless power transfer functions, power could also be transferred from the battery in the vehicle to the power network 118. Further description of the operation of the wireless power transfer system 100 focuses on power transfer from the power supply 114 to the electric vehicle 102. It should, however, be noted while considering the following description that power transfer may also happen in the reverse direction. That is to say, power may be delivered from the battery 104 in the electric vehicle 102 via the wireless power transfer units to the power supply 114 and out to the power network 118. Such a system is generally called Vehicle-to-Home (V2H) or Vehicle-to-Grid (V2G), or more generically, V2x.

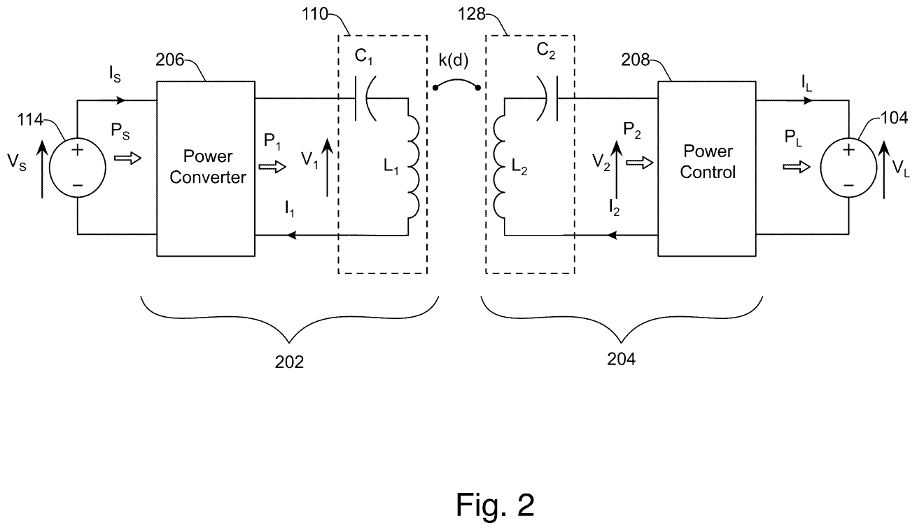

FIG. 2 is a schematic diagram of electrical elements of the wireless power transfer system of FIG. 1. Electrically, the wireless power transfer system 200 comprises base-side circuitry 202 excluding the power supply 114 and including the base-side wireless power transfer coil 110, and vehicle-side circuitry 204 including the vehicle-side wireless power transfer coil 128 and excluding a load (e.g., the battery 104). The base-side circuitry 202 operates to convert energy from the power supply 114 into a suitable form to drive the base-side wireless power transfer coil 110. The vehicle-side circuitry 204 operates to control the application of energy received by the vehicle-side wireless power transfer coil 128 to the vehicle's battery 104.

Electrically, the base-side wireless power transfer coil 110 is represented by inductor L₁. The capacitor C₁ in series with the wireless power transfer coil L₁ (as shown) or in parallel (or another mix of parallel and series components) creates an LC circuit that resonates at a given frequency. This resonance helps to optimize power transfer between the wireless power transfer coils. Values of L and C are selected with the operating frequency of the WEVC system in mind. Similarly, the vehicle-side wireless power transfer coil 128 is represented by inductor L₂. The capacitor C₂ in series with the wireless power transfer coil L₂ (as shown) or in parallel (or another mix of parallel and series components) creates an LC circuit that resonates at a given frequency.

The power supply 114 supplies power Pₛ to a base-side power converter 206. The power may be supplied at local AC power grid voltage levels Vs (e.g., domestic levels of 120 Volts (V) or 240 V at 60 Hertz (Hz) in the U.S. and 220 V at 50 Hz in Europe, or industrial levels and polyphase supplies for higher power implementations), or it may be DC power from a local power supply or DC grid. The base-side power converter 206 converts the incoming power to a power signal P₁ running at a system voltage V1 and frequency to drive the base-side wireless power transfer coil 110. This may be achieved by first converting the signal from the power supply Pₛ into a direct current (DC) signal at the required voltage and then using a converter such as an H-bridge (not shown) to convert the DC signal into the power signal P₁ for the wireless power transfer coil 110. WEVC systems may be operated at a range of operating frequencies around ˜85 kHz, as specified in SAE standard J2954. Operating within a defined range allows the system to operate at different frequencies depending on different alignment conditions, helping reduce detuning effects and hence improving system efficiency.

The base-side power converter 206 ensures that the output power signal P₁ is tuned and matched to the base-side wireless power transfer coil 110. Among other things, this tuning and matching aims to optimize the efficiency at which power is transferred from the power supply 114 to the base-side wireless power transfer coil 110. The power signal has an associated current I₁ that flows in the wireless power transfer coil 110. This current I₁ causes the coil to create a magnetic field.

In use, when the base-side wireless power transfer coil 110 and the vehicle-side wireless power transfer coil 128 are in close proximity (e.g., the electric vehicle is parked with the wireless power transfer coils 110, 128 aligned and separated by an air gap of distance d) the magnetic field generated by the base-side wireless power transfer coil 110 couples with the vehicle-side wireless power transfer coil 128, as represented by k(d), the coupling factor at distance d. The magnetic field induces a voltage V₂ in the coil in the vehicle power transfer apparatus 124 which creates a power signal P₂ including a current I₂. The current I₂ in the power signal P₂ is received by a vehicle-side power control 208, which includes tuning and matching circuitry (illustrated by capacitor C₂) and power conversion circuitry that converts the current I₂ into a form suitable for the battery 104 (e.g., DC current).

Different applications of wireless power transfer are designed to fulfill different operating conditions. Whether the operating frequency of the system 200 is chosen first and values of the capacitor C₁ and the inductor L₁ are selected accordingly, or whether the values of the capacitor C₁ and the inductor L₁ are chosen first and the operating frequency is selected accordingly is, in practice, an engineering decision. The standardization of the operating frequency for WEVC at the aforementioned 85 kHz is one governing value in designing the wireless power transfer coils 110, 128.

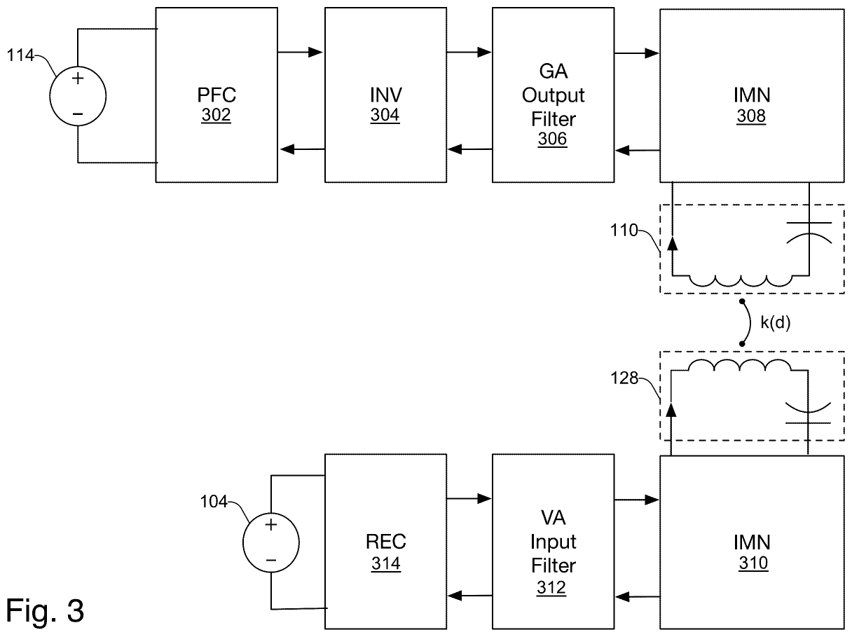

FIG. 3 shows an expanded version of the basic block diagram of FIG. 2, in which the components of the power converter 206 and power control 208 are detailed. In particular, the power input side of the system may include a Power Factor Correction (PFC) circuit 302 or other power converter, such as a DC-DC converter, receiving power from the power supply, an Inverter (INV) 304 converting power to LF power for wireless transmission, a Ground Assembly (GA) Output Filter 306, to be discussed below, and an Impedance Matching Network (IMN) 308 for coupling the LF power into the resonant coil (e.g., wireless power transfer coil 110). Similarly, the power output side of the system includes another IMN 310, a Vehicle Assembly (VA) Input Filter 312, and a Rectifier (REC) 314 to provide DC output power to the battery 104 or other load. In systems that operate bidirectionally, the Inverter 304 and Rectifier 314 may be replaced by bidirectional inverter/rectifiers.

The GA Output Filter 306 and VA Input Filter 312 serve to suppress emissions from the system by removing common-mode (CM) noise from the power signal provided to or received from the IMNs 308 and 310. Each of these filters includes a common-mode choke (CMC) that presents a high CM impedance over a wide range of frequencies, while allowing a high fundamental differential-mode (DM) current at the operating frequency of ˜85 kHz.

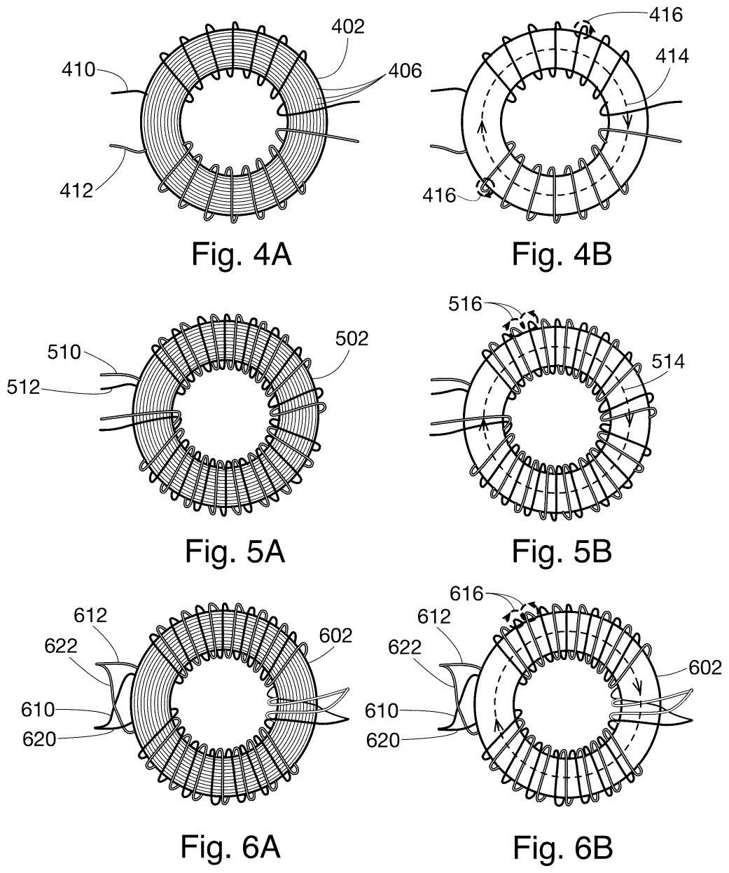

In some examples, the common-mode choke used in both the GA Output Filter 306 and the VA Input Filter 312 is constructed as shown in FIGS. 4A and 4B. A central core 402 is formed from a plurality of thin layers 406 of magnetically permeable material, such as amorphous iron alloys or nano-sized crystalized amorphous magnetic material, commonly called Nanocrystalline (NC). One example alloy used for NC material is FeSiBCuNb; other alloys may also be used. NC is particularly useful for filtering out high frequency harmonics. Thin strips of NC material have a high permeability to magnetic fields in the plane of the strip, but a low permeability to fields in directions normal to that plane. As a result, the core 402 formed from laminating multiple strips into an annular ring is permeable to tangential magnetic fields, but not to fields penetrating the core in a radial direction. The core 402 is shown as a circular shape with an open center, that is, an annulus. Other shapes may also be used, including toroid, elliptical, square, rectangular, or U-shaped.

Two wires 410, 412 are wrapped around separate sections of the core 402. One wire (e.g., wire 410) is shown as black wire and the other (e.g., wire 412) as white to differentiate them in the figures. The wire leads entering and exiting on opposite sides of the core leads to low parasitic capacitance, maintaining the HF emission suppression provided by the filter. As shown in FIG. 4B, the magnetic field 414 arising from wrapping the wires around the core is parallel to the laminations forming the core, and thus is confined to the core. The fields resulting from common-mode current (e.g., noise) in the wire in the two sections are oriented the same direction. Leakage flux 416, 418 from the individual wires 410 and 412, however, is perpendicular to the layers forming the core 402, which can result in heating of that material when high DM currents are passed through the filter during power transfer.

An alternative configuration is shown in FIGS. 5A and 5B. Here, two wires 510, 512 are wound together all the way around the core (e.g., core 502), providing a bifilar winding in which the wire leads enter and exit on the same side of the core. Tangential fields 514 resulting from CM current are still confined to the core, and now the high DM current in adjacent windings produces magnetic fields 516 that cancel each other, resulting in little DM leakage flux penetrating the core and causing heating. However, the bifilar winding results in high parasitic capacitance between the leads, which undermines the high-frequency emission suppression provided by the laminated core.

FIGS. 6A and 6B show a hybrid configuration, combining the aspects of a sectional configuration of FIGS. 4A and 4B and the bifilar configuration of FIGS. 5A and 5B. Here, two sets of bifilar windings (e.g., wires 610 and 612 form a first set, wires 620 and 622 form a second set) are wrapped around two separate sections of the core (e.g., core 602). In the illustrated example, the two separate sections are separated by the entry and exit leads. Wires 610 and 620 and wires 612 and 622 from the two sections, respectively, are joined at the entry and exit leads. Within each section, DM leakage flux is cancelled as in FIGS. 5A and 5B (e.g., adjacent windings produce magnetic fields 616 that cancel each other) so heating of the core is minimized, while the positioning of the leads decreases the parasitic capacitance of the filter, so high-frequency emissions are suppressed as in the sectional configuration of FIGS. 4A and 4B. The two sections each span up to 180° of the core. In one example, the two sections each span less than half of a perimeter of the core. The wires used may be solid wire or stranded wire, in particular Litz wire.

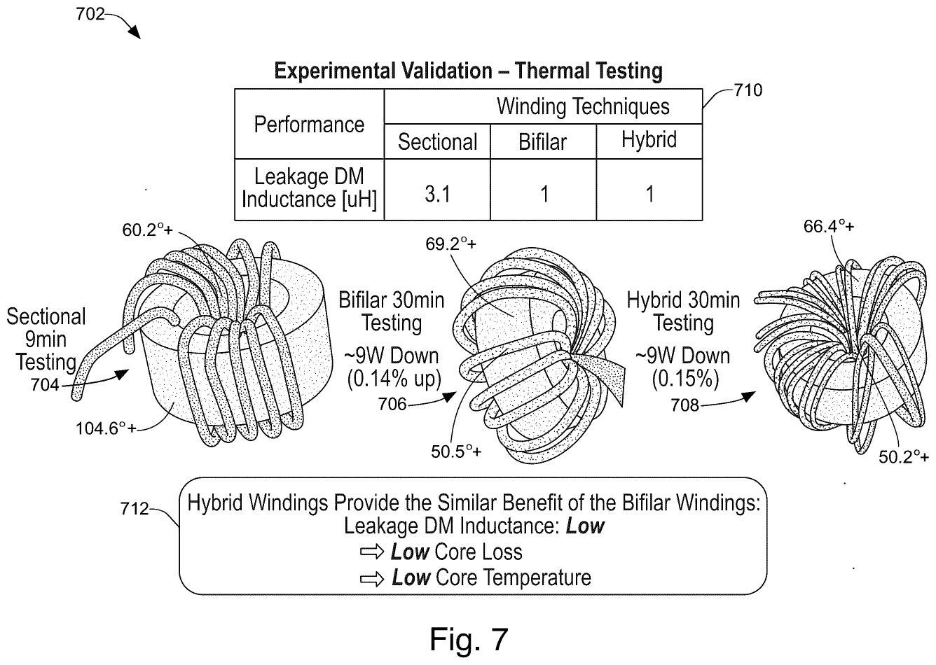

FIG. 7 shows experimental results 702 from thermal testing of the three winding topologies of FIGS. 4A-6B. For example, a sectional winding 704 corresponds to the topology of FIGS. 4A and 4B, a Bifilar winding 706 corresponding to the topology of FIGS. 5A and 5B, and a Hybrid winding 708 corresponds to the topology of FIGS. 6A and 6B. For the sectional winding 704, the core reached 104.6° C. after 9 minutes, while the winding reached a temperature of 60.2° C. In contrast, the cores in the Bifilar winding 706 and the Hybrid winding 708 reached only 69.2° C. and 66.4° C., respectively, after 30 minutes, while the windings reached 50.5° C. and 50.2° C., respectively. In these experimental tests, as shown at 710, the sectional winding 704 had 3.1 microhenry (μH) of leakage DM inductance, while both the Bifilar winding 706 and the Hybrid winding 708 had only 1 μH of leakage DM inductance, respectively. Further, the hybrid windings provide similar benefits 712 to the bifilar windings. For example, both the bifilar windings and the hybrid windings have low leakage DM inductance, low core loss, and low core temperature.

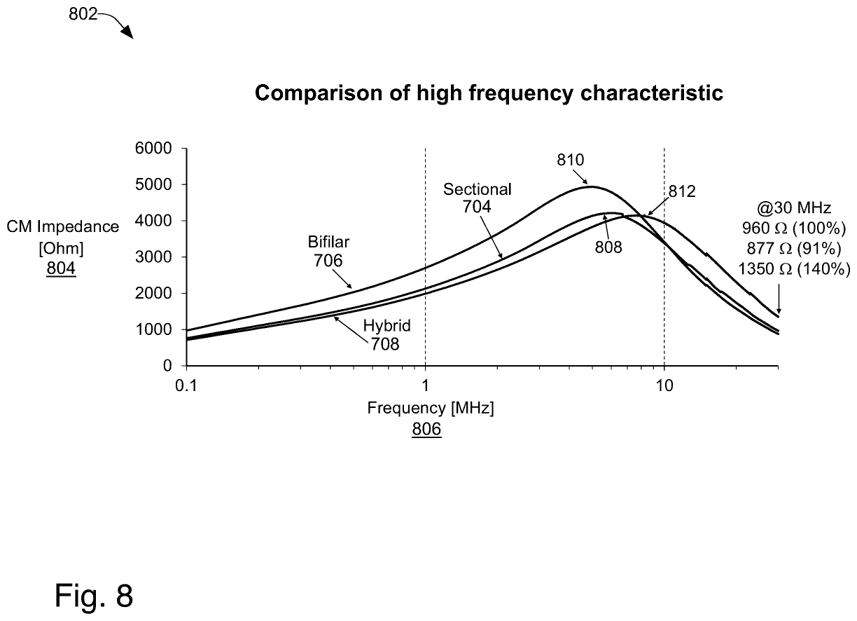

FIG. 8 shows a comparison chart 802 of high frequency CM impedance of the three topologies described above. The chart 802 shows measurements of CM impedance 804 in Ohms (Q) relative to frequency 806 in MHz. Impedance of the Sectional winding 704 peaks at 808 with a value just over 4000 Q at 6 MHZ, and the Bifilar winding 706 peaks at 810 at 5000 Q at 5 MHz. The Hybrid winding 708 matches the sectional winding 704 at a peak impedance 812 of about 4000 Q, but raises the peak frequency to 8 MHz, and is higher than both alternative windings (e.g., the Sectional winding 704 and the Bifilar winding 706), 1350 Ω vs 960 Ω and 877 Ω for the Sectional winding 704 and the Bifilar winding 706, respectively, at 30 MHz. For particular WPT systems, it was found that high frequency suppression was needed around 5-15 MHz. With its peak raised to 8 MHz and higher impedance at all frequencies above that, the Hybrid winding 708 shows significant improvement over the Sectional winding 704 and Bifilar winding 706 alternatives. The Hybrid winding 708 additionally has a high impedance above 30 MHz, which may eliminate the need for an additional CM choke at that frequency. Accordingly, benefits of the Hybrid winding 708 include high self-resonance frequency and high HF emission suppression.

The various illustrative logical blocks, modules, circuits, and method steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions should not be interpreted as causing a departure from the scope of the described aspects.

Although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus for filtering signals, the apparatus comprising:
a plurality of laminations forming a core;
a first bifilar winding wrapped around a first portion of the core; and
a second bifilar winding wrapped around a second portion of the core.

2. The apparatus of claim 1, wherein:
the first and second portions of the core do not overlap.

3. The apparatus of claim 1, wherein:
each of the first and second portions of the core span less than half of a perimeter of the core.

4. The apparatus of claim 1, wherein:
the plurality of laminations comprise nanocrystalline (NC) material.

5. The apparatus of claim 1, wherein:
the plurality of laminations comprise iron alloy material other than nanocrystalline (NC) material.

6. The apparatus of claim 1, wherein:
each of the first and second bifilar windings comprises respective first and second wires, wherein the respective first and second wires maintain a parallel arrangement, relative to each other, when wrapped around a corresponding section of the core.

7. The apparatus of claim 6, wherein:
each of the first and second wires comprises Litz wire.

8. The apparatus of claim 6, wherein:
each of the first and second wires comprises solid wire.

9. An apparatus for transmitting power wirelessly, the apparatus comprising:
a power input;
a power converter coupled to the power input and configured to provide high-frequency (HF) current;
an output coil; and
an output filter between the power converter and the output coil, the output filter comprising:
a plurality of laminations forming a core;
a first bifilar winding wrapped around a first portion of the core; and
a second bifilar winding wrapped around a second portion of the core.

10. The apparatus of claim 9, wherein:
the first and second portions of the core do not overlap.

11. The apparatus of claim 9, wherein:
each of the first and second portions of the core span less than half of a perimeter of the core.

12. The apparatus of claim 9, wherein:
the plurality of laminations comprise nanocrystalline (NC) material.

13. The apparatus of claim 9, wherein:
the plurality of laminations comprise iron alloy material other than nanocrystalline (NC) material.

14. The apparatus of claim 9, wherein:
each of the first and second bifilar windings comprises respective first and second wires, wherein the respective first and second wires maintain a parallel arrangement, relative to each other, when wrapped around a corresponding section of the core.

15. The apparatus of claim 14, wherein:
each of the first and second wires comprises Litz wire.

16. The apparatus of claim 14, wherein:
each of the first and second wires comprises solid wire.

17. An apparatus for receiving wirelessly transmitted power, the apparatus comprising:
an input coil;
a power converter coupled to an output and configured to provide current suitable for a load; and
an input filter between the input coil and the power converter, the input filter comprising:
a plurality of laminations forming a core;
a first bifilar winding wrapped around a first portion of the core; and
a second bifilar winding wrapped around a second portion of the core.

18. The apparatus of claim 17, wherein:
the first and second portions of the core do not overlap.

19. The apparatus of claim 17, wherein:
each of the first and second portions of the core span less than half of a perimeter of the core.

20. The apparatus of claim 17, wherein:
the plurality of laminations comprise nanocrystalline (NC) material; or
the plurality of laminations comprise iron alloy material other than nanocrystalline (NC) material.
